(19) United States
(12) Patent Application Publication
(10) Pub. No.: US 2010/0187694 A1
(43) Pub. Date: Jul. 29, 2010

(54) Through-Silicon Via Sidewall Isolation Structure

(76) Inventors: Chen-Hua Yu, Hsin-Chu (TW); Wen-Chih Chiou, Miaoli (TW); Weng-Jin Wu, Hsin-Chu (TW)

Correspondence Address: SLATER & MATSIL, L.L.P., 17950 PRESTON ROAD, SUITE 1000, DALLAS, TX, 75252, US

(21) Appl. No.: 12/617,494

(22) Filed: Nov. 12, 2009

Related U.S. Application Data
(60) Provisional application No. 61/147,871, filed on Jan. 28, 2009.

(51) Int. Cl. H01L 23/48; H01L 21/768

(52) U.S. Cl. 257/751; 257/774; 438/653; 257/E23.011; 257/E21.584

(57) ABSTRACT

A system and method for an improved through-silicon via isolation structure is provided. An embodiment comprises a semiconductor device having a substrate with electrical circuitry formed thereon. One or more dielectric layers are formed over the substrate, and an opening is etched into the structure extending from a surface of the one or more dielectric layers through the one or more dielectric layers into the substrate; the opening having sidewalls. A low-K dielectric layer is formed over the sidewalls of the opening. The opening is filled with a conductive material and/or a barrier layer creating a through-silicon via that is isolated from the surrounding substrate by the low-K dielectric layer.

This application claims the benefit of U.S. Provisional Application No. 61/147,871, filed on Jan. 28, 2009, entitled “Through-Silicon Via Sidewall Isolation Structure,” which application is hereby incorporated herein by reference.

### TECHNICAL FIELD

The present invention relates generally to a system and method for improved through-silicon vias and, more particularly, to a system and method for a through-silicon via sidewall isolation structure.

### BACKGROUND

Since the invention of the integrated circuit (IC), the semiconductor industry has experienced rapid growth due to continuous improvements in the integration density of various electronic components (e.g., transistors, diodes, resistors, capacitors, etc.). For the most part, this improvement in integration density has come from repeated reductions in minimum feature size, which allows more components to be integrated into a given area.

In an attempt to further increase circuit density, three-dimensional (3D) ICs have been investigated. In a typical formation process of a 3D IC, two dies are bonded together and electrical connections are formed between each die and contact pads on a substrate. For example, one attempt involved bonding two dies on top of each other. The stacked dies were then bonded to a carrier substrate and wire bonds electrically coupled the contact pads on each die to contact pads on the carrier substrate. This attempt, however, requires a carrier substrate larger than the dies for the wire bonding.

More recent attempts have focused on through-silicon vias (TSVs). Generally, a TSV is formed by etching a vertical via through a substrate and filling the via with a conductive material, such as copper. The backside of the substrate is thinned to expose the TSV, and an electrical contact is formed to the TSV.

As part of the TSV formation process, a barrier layer is generally formed between the conductive material of the TSV and the surrounding substrate. Typically, the barrier layer is an oxide or nitride layer formed by a physical vapor deposition (PVD) or a chemical vapor deposition (CVD) process. However, the barrier layer formation processes have difficulty in forming a thin layer along the sidewalls of the via formed in the substrate and often result in a thick layer on the surface of the substrate. When the excess conductive material on the surface of the substrate is planarized, such as with a chemical mechanical polish (CMP), leaving only the conductive material in the via, the thick barrier layer on the surface of the substrate results in a large post CMP variation. Additionally, the thicker barrier layer reduces the effective area of the via resulting in difficulties when attempting to fill the via with conductive material.

Accordingly, there is a need for a better method of forming the barrier layer on the via sidewall that results in a thinner barrier layer on the via sidewall while also reducing the capacitance along the via sidewall.

### SUMMARY OF THE INVENTION

These and other problems are generally solved or circumvented, and technical advantages are generally achieved, by embodiments of the present invention which provide a semiconductor device having an improved through-silicon via with a sidewall isolation structure.

In accordance with an embodiment of the present invention, a semiconductor device comprising a substrate having electrical circuitry formed thereon is provided. One or more dielectric layers are formed over the substrate, and an opening extending through the one or more dielectric layers into the substrate is formed. The opening is filled with a conductive material, and a low-K dielectric layer is interposed between the substrate and the conductive material.

In accordance with another embodiment of the present invention, a method for creating a semiconductor device is provided. The method comprises providing a substrate, and forming an opening in the substrate extending from a first surface of the substrate into the substrate, the opening having sidewalls. A low-K dielectric layer is formed along the sidewalls of the opening, and a conductive layer is formed over the first surface of the substrate, filling in the opening.

In accordance with yet another embodiment of the present invention, a method for creating a semiconductor device is provided. The method comprises providing a substrate having a circuit side and a backside opposite the circuit side, and forming circuitry on the circuit side of the substrate. One or more dielectric layers are formed over the circuit side of the substrate, and an opening is formed in the substrate extending from a surface of the one or more dielectric layers, the opening having sidewalls. The method further comprises forming a low-K dielectric layer over the sidewalls of the opening, and forming a conductive layer over the low-K dielectric layer such that the opening is filled by the conductive layer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1-8 illustrate intermediate stages in the process for forming a through-silicon via with improved sidewall isolation.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

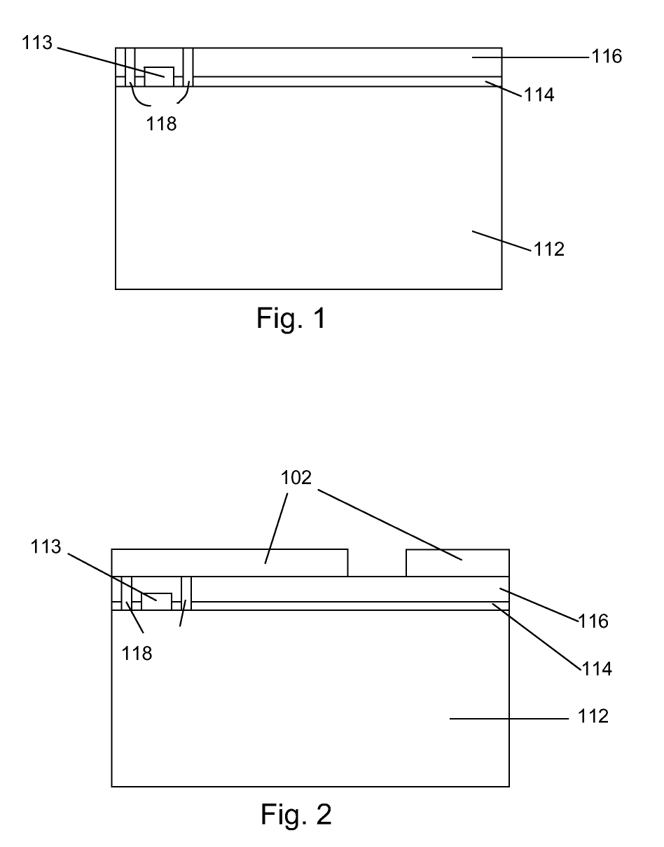

FIGS. 1-8 are cross-sectional views of intermediate stages in the making of an embodiment of the present invention. Referring first to FIG. 1, a substrate 112 is shown having electrical circuitry 113 formed thereon. The substrate 112 may comprise, for example, bulk silicon, doped or undoped, or an active layer of a semiconductor-on-insulator (SOI) substrate. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, typically a silicon or glass substrate. Other substrates, such as a multi-layered or gradient substrate may also be used.

The electrical circuitry 113 formed on the substrate 112 may be any type of circuitry suitable for a particular application. In an embodiment, the circuitry includes electrical devices formed on the substrate with one or more dielectric layers overlying the electrical devices. Metal layers may be formed between dielectric layers to route electrical signals between the electrical devices. Electrical devices may also be formed in one or more dielectric layers.

For example, the electrical circuitry 113 may include various N-type metal-oxide semiconductor (NMOS) and/or P-type metal-oxide semiconductor (PMOS) devices, such as transistors, capacitors, resistors, diodes, photo-diodes, fuses, and the like, interconnected to perform one or more functions. The functions may include memory structures, processing structures, sensors, amplifiers, power distribution, input/output circuitry, or the like. One of ordinary skill in the art will appreciate that the above examples are provided for illustrative purposes only to further explain applications of the present invention and are not meant to limit the present invention in any manner. Other circuitry may be used as appropriate for a given application.

Also shown in FIG. 1 are an etch stop layer 114 and an inter-layer dielectric (ILD) layer 116. The etch stop layer 114 is preferably formed of a dielectric material having a different etch selectivity from adjacent layers, e.g., the underlying substrate 112 and the overlying ILD layer 116. In an embodiment, the etch stop layer 114 may be formed of SiN, SiCN, SiCO, CN, combinations thereof, or the like, deposited by chemical vapor deposition (CVD) or plasma-enhanced CVD (PECVD) techniques.

The ILD layer 116 may be formed, for example, of a low-K dielectric material, such as silicon oxide, phosphosilicate glass (PSG), borophosphosilicate glass (BPSG), fluorinated silicate glass (FSG), SiOₓC_{y}, Spin-On-Glass, Spin-On-Polymers, silicon carbon material, compounds thereof, composites thereof, combinations thereof, or the like, by any suitable method known in the art, such as spinning, CVD, and PECVD. It should also be noted that the etch stop layer 114 and the ILD layer 116 may each comprise a plurality of dielectric layers, with or without an etch stop layer formed between adjacent dielectric layers.

Contacts 118 are formed through the ILD layer 116 to provide an electrical contact to the electrical circuitry 113. The contacts 118 may be formed, for example, by using photolithography techniques to deposit and pattern a photoresist material on the ILD layer 116 to expose portions of the ILD layer 116 that are to become the contacts 118. An etch process, such as an anisotropic dry etch process, may be used to create openings in the ILD layer 116. The openings are, preferably, lined with a diffusion barrier layer and/or an adhesion layer (not shown), and filled with a conductive material. Preferably, the diffusion barrier layer comprises one or more layers of TaN, Ta, TiN, Ti, CoW, or the like, and the conductive material comprises copper, tungsten, aluminum, silver, and combinations thereof, or the like, thereby forming the contacts 118 as illustrated in FIG. 1.

Referring now to FIG. 2, a mask layer 102 formed overlying the ILD layer 116 is shown. In an embodiment, the mask layer 102 comprises a photoresist material that has been applied and patterned on the underlying ILD layer 116, although other materials having a high-etch selectivity with the underlying material of the ILD layer 116 may be used. Generally, the mask layer 102 may be formed of a photoresist material by depositing a layer of photoresist material and exposing the photoresist material in accordance with a desired pattern. After the photoresist material is exposed, the photoresist material is developed to remove unwanted portions of the photoresist material, thereby forming the mask layer 102 as illustrated in FIG. 2. Other materials, such as SiN, SiO₂, or the like, may be used to form the mask layer.

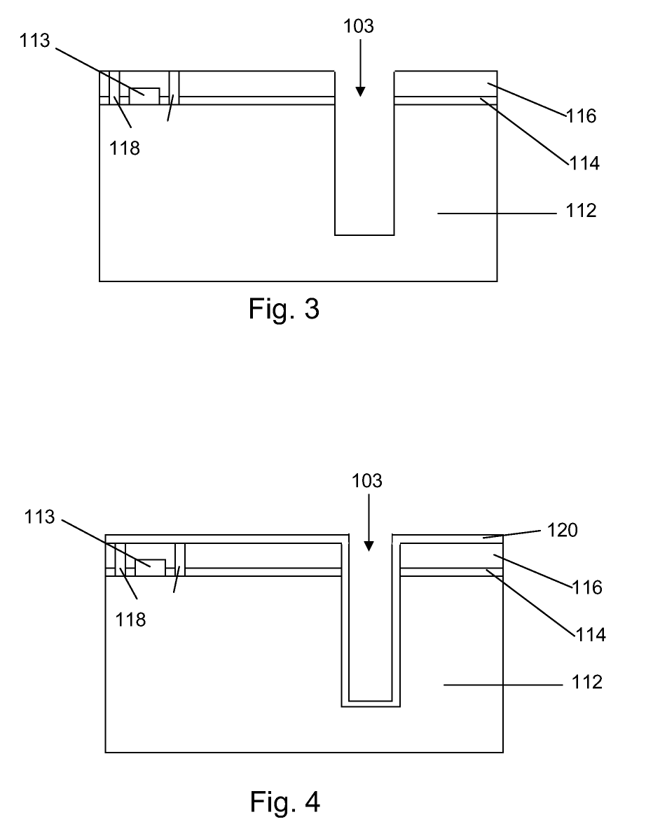

Thereafter, one or more etching processes may be performed to create opening 103 as illustrated in FIG. 3. In an embodiment, a timed etching process, such as an anisotropic dry etch process, is performed until a desired depth for the opening 103 is obtained in the substrate 112. It should be understood that the etch processes described herein may be accomplished in single etch processes or multiple etch processes. For example, a first etch process may be performed to etch through the ILD layer 116, and one or more second etch processes may be performed to etch through the etch stop layer 114 and/or the substrate 112. It should also be understood that the openings may be formed by other methods, such as milling, laser techniques, or the like.

Thereafter, a spin-on coating process is used to form a low-K dielectric layer 120 over the ILD layer 116 as illustrated in FIG. 4. Preferably, the low-K dielectric layer 120 covers the sidewalls of the opening 103. The dielectric constant of the low-K dielectric layer 120 is preferably less than about 4. The low-K dielectric layer 120 may be formed, for example, of SOG related material, methyl silsesquioxane (MSQ), hydrogen silsesquioxane (HSQ), and all spin-on low k materials used to form interconnects, by any suitable spinning method known in the art.

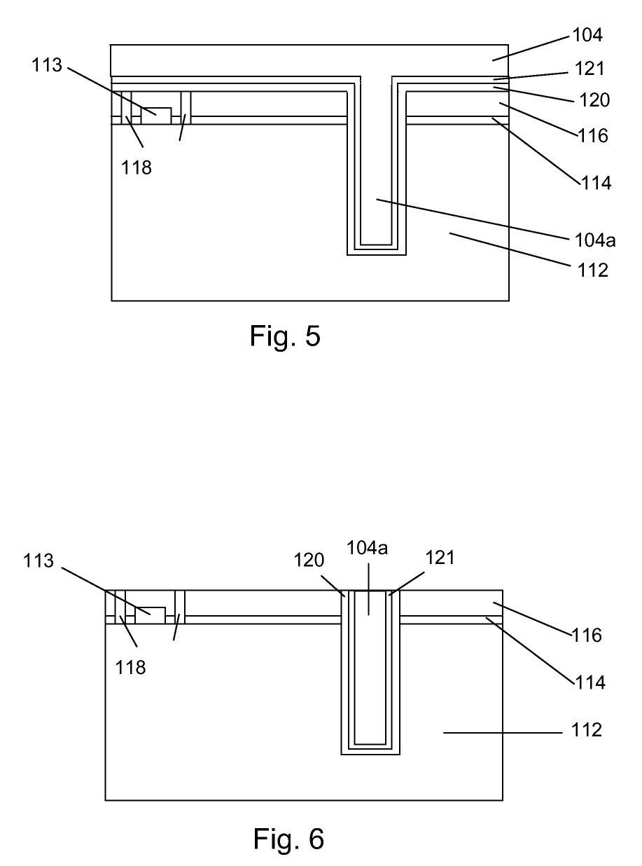

FIG. 5 illustrates a conductive layer 104 and an optional barrier layer 121 filling the opening 103 in accordance with an embodiment of the present invention. The conductive layer 104 is preferably copper, but can be any suitable conductive material, such as copper alloys, aluminum, tungsten, silver, polysilicon, and combinations thereof. In an embodiment in which the conductive material is copper, the conductive layer 104 may be formed by depositing a seed layer and then performing an electroplating process. The filling of the opening 103 with the conductive material of conductive layer 104 creates through-silicon via (TSV) 104a.

Also shown in FIG. 5 is the optional barrier layer 121 formed over the low-K dielectric layer 120 prior to forming the conductive layer 104. The optional barrier layer 121 preferably comprises a conductive material such as titanium nitride, although other materials, such as tantalum, tantalum nitride, or titanium, may alternatively be utilized. The optional barrier layer 121 is preferably formed using a CVD process, such as PECVD. However, other alternative processes, such as sputtering or metal organic chemical vapor deposition (MOCVD), may be used. The optional barrier layer 121 reduces the incidence of diffusion between the conductive material subsequently placed into the opening 103 and the surrounding materials, e.g., the low-K dielectric layer 120 and the substrate 112.

One of ordinary skill in the art will appreciate that the use of the spin-on coating process to form the low-K dielectric layer 120 allows for formation of a relatively thin uniform coating along the sidewall of the opening 103. The low-K dielectric layer 120 also provides additional isolation between the TSV 104a and the substrate 112 thereby achieving a reduction in capacitance along the sidewall of the TSV 104a. Furthermore, the thinner isolation structure of the low-K dielectric layer 120 underlying the optional barrier layer 121 creates an increased effective area for the conductive material of the TSV 104a, thus increasing the effectiveness of the TSV 104a.

It should be noted that, while the TSV 104a is illustrated as extending from the ILD layer 116 into the substrate 112, other TSV configurations may be used. For example, embodiments of the present invention may utilize TSVs that extend from a surface of the substrate 112, subsequently formed inter-metal dielectric (IMD) layers, or the like.

Referring to FIG. 6, one or more planarization processes are performed to remove the conductive layer 104, the optional barrier layer 121, and the low-K dielectric layer 120 from the surface of the ILD layer 116. The removal process may be performed using a mechanical grinding process, a chemical mechanical polishing (CMP) process, an etching process, and/or a combination thereof. Because a relatively thin on-field deposition results from the spin-on process used to form the low-K dielectric layer, the post CMP variation is significantly reduced.

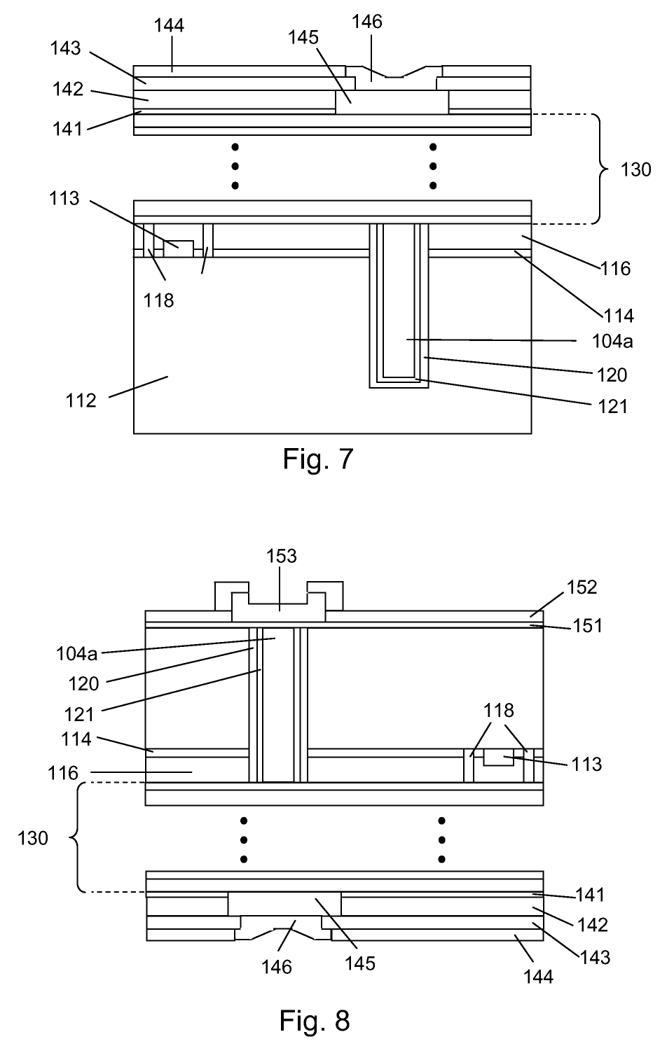

As shown in FIG. 7, one or more inter-metal dielectric (IMD) layers 130 and the associated metallization layers (not shown) are formed over the ILD layer 116. Generally, the one or more IMD layers 130 and the associated metallization layers are used to interconnect the electrical circuitry 113 to each other and to provide an external electrical connection. The IMD layers 130 are preferably formed of a low-K dielectric material, such as fluorosilicate glass (FSG) formed by PECVD techniques or high-density plasma CVD (HDPCVD), or the like, and may include intermediate etch stop layers, similar to the etch stop layer 114.

Also shown in FIG. 7, subsequent wafer processes are performed to provide an electrical connection to an external device. For example, a first contact pad 145 and an under bump metallization (UBM) 146 are formed over the IMD layers 130. A passivation layer 141 and a first insulation layer 142 are formed to insulate the first contact pad 145 from other contact pads on the device. A second insulation layer 143 and a third insulation layer 144 are formed to insulate the UBM 146 from other UBMs on the device and from the external environment.

FIG. 8 illustrates backside processes performed to expose the TSV 104a for electrical connection to other semiconductor devices. In an embodiment, a planarization process, such as a CMP process, is performed to expose the surface of the TSV 104a as shown in FIG. 8. After the backside of the substrate 112 is thinned, a second contact pad 153 is preferably formed over the TSV 104a. A backside passivation layer 151 is formed over the backside of the substrate 112 to insulate the second contact pad 153 from the substrate 112, and other contact pads that may be formed on the backside of the substrate 112. A first backside insulation layer 152 is formed over the backside passivation layer 151 in order to further insulate the contact pad 153 from other contact pads on the backside of the substrate 112 and the external environment.

It should be appreciated that the present invention provides a TSV with a thinner sidewall isolation structure. The process described herein forms an isolation structure using a low-K dielectric material that decreases the capacitance along the sidewalls of the TSV while also providing a greater area for filling of a conductive material into the TSV, thus increasing the likelihood of successful TSV formation. Forming the isolation structure using a spin-on coating process also results in a lower post CMP variation due to a thinner on field film deposition.

The embodiments and processes described above are meant as illustrations only and are not intended to limit the scope of the invention. Alternative process and structures are contemplated. For example, an additional thinning process may be performed after the CMP process to recess the backside of the substrate 112 further exposing TSV 104a. Similarly, the contact pad 145 and the UBM 146 may alternatively include a redistribution layer, a conductive bump and/or additional insulation layers. In addition, the backside processes described above may also include the formation of a redistribution layer, a conductive bump, a UBM, and/or additional insulation layers.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a substrate having electrical circuitry formed thereon;
one or more dielectric layers formed over the substrate;
an opening extending through the one or more dielectric layers into the substrate, the opening filled with a conductive material; and
a low-K dielectric layer interposed between the substrate and the conductive material.

2. The semiconductor device of claim 1, further comprising a barrier layer interposed between the low-K dielectric layer and the conductive material.

3. The semiconductor device of claim 1, wherein the low-K dielectric layer comprises a material having a dielectric constant of less than about 4.

4. The semiconductor device of claim 1, wherein the low-K dielectric layer comprises a material selected from the group consisting of Si—O—H, Si—O—C—H, and combinations thereof

5. The semiconductor device of claim 1, wherein the conductive layer comprises a material selected from the group consisting of copper, copper alloys, aluminum, tungsten, silver, polysilicon, and combinations thereof.

6. A method for creating a semiconductor device, the method comprising:
providing a substrate having a circuit side and a backside opposite the circuit side;
forming an opening in the substrate extending from the circuit side into the substrate, the opening having sidewalls;
forming a low-K dielectric layer along the sidewalls of the opening;
forming a conductive layer in the opening; and
exposing the conductive layer on the backside of the substrate.

7. The method of claim 6, wherein the method further comprises forming a barrier layer over the low-K dielectric layer prior to forming the conductive layer.

8. The method of claim 6, wherein the forming the low-K dielectric layer comprises a spin-on coating process.

9. The method of claim 6, wherein the low-K dielectric layer comprises a dielectric material having a dielectric constant of less than about 4.

10. The method of claim 6, wherein the low-K dielectric layer comprises a dielectric material selected from the group of materials consisting essentially of Si—O—H, Si—O—C—H, or combinations thereof.

11. The method of claim 6, further comprising the opening extending through one or more dielectric layers formed on the circuit side of the substrate.

12. The method of claim 6, wherein the forming the conductive layer comprises an electroplating process.

13. The method of claim 6, wherein the conductive layer comprises a material selected from the group consisting of copper, copper alloys, aluminum, tungsten, silver, polysilicon, and combinations thereof.

14. A method for creating a semiconductor device, the method comprising:
providing a substrate having a circuit side and a backside opposite the circuit side;
forming circuitry on the circuit side of the substrate;
forming one or more dielectric layers over the circuit side of the substrate;
forming an opening in the substrate extending from a surface of the one or more dielectric layers, the opening having sidewalls;
forming a low-K dielectric layer over the sidewalls of the opening; and
forming a conductive layer over the low-K dielectric layer such that the opening is filled with the conductive layer.

15. The method of claim 14, wherein the method further comprises forming a barrier layer over the low-K dielectric layer prior to forming the conductive layer.

16. The method of claim 14, wherein the forming the low-K dielectric layer comprises a spin-on coating process.

17. The method of claim 14, wherein the low-K dielectric layer comprises a material having a dielectric constant of less than about 4.

18. The method of claim 14, wherein the low-K dielectric layer comprises a material selected from the group consisting of Si—O—H, Si—O—C—H, or combinations thereof.

19. The method of claim 14, further comprising exposing the conductive layer on the backside of the substrate.

20. The method of claim 14, wherein the forming the conductive layer comprises an electroplating process.
